(19) United States
(12) Patent Application Publication
(10) Pub. No.: US 2024/0405514 A1
(43) Pub. Date: Dec. 5, 2024

(54) SEMICONDUCTOR OPTICAL ELEMENT, MEASUREMENT DEVICE AND LIGHT SOURCE DEVICE USING SEMICONDUCTOR OPTICAL ELEMENT, AND METHOD OF MANUFACTURING SEMICONDUCTOR OPTICAL ELEMENT

(71) Applicant: NICHIA CORPORATION, Anan-shi (JP)

(72) Inventor: Masahiko SANO, Yokohama-shi (JP)

(73) Assignee: NICHIA CORPORATION, Anan-shi (JP)

(21) Appl. No.: 18/675,279

(22) Filed: May 28, 2024

(30) Foreign Application Priority Data
May 31, 2023 (JP) 2023-090355

(51) Int. Cl. H01S 5/20; G01S 7/481; H01S 5/14; H01S 5/22; H01S 5/32

(52) U.S. Cl. CPC H01S 5/2054; G01S 7/4814; H01S 5/14; H01S 5/22; H01S 5/321; H01S 2302/00

(57) ABSTRACT

A semiconductor optical element includes a first indirect bandgap semiconductor part that includes a first-conductivity-type impurity; a second indirect bandgap semiconductor part that includes a first-conductivity-type impurity; a third indirect bandgap semiconductor part that includes a second-conductivity-type impurity; a fourth indirect bandgap semiconductor part that includes a second-conductivity-type impurity; and a fifth indirect bandgap semiconductor part that includes a second-conductivity-type impurity. The first indirect bandgap semiconductor part has one or more first recesses. The one or more first recesses contain a medium having a refractive index lower than a refractive index of the second indirect bandgap semiconductor part. The fifth indirect bandgap semiconductor part has one or more second recesses. The one or more second recesses contain a medium having a refractive index lower than a refractive index of the fourth indirect bandgap semiconductor part.

### CROSS-REFERENCE TO RELATED APPLICATIONS

This application is based on and claims priority to Japanese Patent Application No. 2023-090355, filed on May 31, 2023, the entire contents of which are incorporated herein by reference.

### BACKGROUND

The present disclosure relates to a semiconductor optical element, a measurement device and a light source device using the semiconductor optical element, and a method of manufacturing the semiconductor optical element.

In general, light emitting elements such as laser diodes and light emitting diodes are fabricated by using direct bandgap semiconductors such as III-V compound semiconductors. However, in many cases, electronic devices are formed of silicon (Si) as a main material. If semiconductor optical elements can be formed by using indirect bandgap semiconductors represented by Si, the semiconductor optical elements can be easily combined with Si electronic devices, thus widening the application range.

A semiconductor light emitting device including a light emitting section formed at a p-n homojunction between a p-type semiconductor layer and an n-type semiconductor layer, which are adjacent to each other in a plane parallel to the surface of a silicon substrate, is known. The semiconductor light emitting device has a configuration in which the p-n homojunction is corrugated with a period corresponding to an emission wavelength (see Japanese Patent Publication No. 2008-305853, for example). Silicon oxide films are provided on an upper layer and a lower layer of the light emitting section, and thus light is confined.

### SUMMARY

It is desirable to improve performance such as light confinement performance and wavelength selectivity when a semiconductor optical element is manufactured by using an indirect bandgap semiconductor. One aspect of the present disclosure provides a semiconductor optical element using an indirect bandgap semiconductor and a method of manufacturing the semiconductor optical element.

According to one embodiment of the present disclosure, a semiconductor optical element includes a first indirect bandgap semiconductor part that includes a first-conductivity-type impurity; a second indirect bandgap semiconductor part that includes a first-conductivity-type impurity; a third indirect bandgap semiconductor part that includes a second-conductivity-type impurity; a fourth indirect bandgap semiconductor part that includes a second-conductivity-type impurity; and a fifth indirect bandgap semiconductor part that includes a second-conductivity-type impurity. The first indirect bandgap semiconductor part, the second indirect bandgap semiconductor part, the third indirect bandgap semiconductor part, the fourth indirect bandgap semiconductor part, and the fifth indirect bandgap semiconductor part are layered in this order. The first indirect bandgap semiconductor part has one or more first recesses. The one or more first recesses contain a medium having a refractive index lower than a refractive index of the second indirect bandgap semiconductor part. The fifth indirect bandgap semiconductor part has one or more second recesses. The one or more second recesses contain a medium having a refractive index lower than a refractive index of the fourth indirect bandgap semiconductor part.

According to one embodiment of the present disclosure, a method of manufacturing a semiconductor optical element includes preparing a layered body in which a first indirect bandgap semiconductor part that includes a first-conductivity-type impurity, a second indirect bandgap semiconductor part that includes a first-conductivity-type impurity, a third indirect bandgap semiconductor part that includes a second-conductivity-type impurity, a fourth indirect bandgap semiconductor part that includes a second-conductivity-type impurity, and a fifth indirect bandgap semiconductor part that includes a second-conductivity-type impurity are layered in this order; forming one or more first recesses in the first indirect bandgap semiconductor part of the layered body, the one or more first recesses containing a medium having a refractive index lower than a refractive index of the second indirect bandgap semiconductor part; and forming one or more second recesses in the fifth indirect bandgap semiconductor part of the layered body, the one or more second recesses containing a medium having a refractive index lower than a refractive index of the fourth indirect bandgap semiconductor part.

### BRIEF DESCRIPTION OF THE DRAWINGS

Other objects and further features of the present disclosure will be apparent from the following detailed description when read in conjunction with the accompanying drawings, in which:

FIG. 1A is top view of a semiconductor optical element according to an embodiment;

FIG. 1B is a cross-sectional view of the semiconductor optical element taken along line A-A of FIG. 1A;

FIG. 2 is a schematic perspective view of the semiconductor optical element;

FIG. 3 is a schematic side view of the semiconductor optical element along the resonance direction;

FIG. 4 is a diagram illustrating one modification of the semiconductor optical element;

FIG. 5 is a diagram illustrating another modification of the semiconductor optical element;

FIG. 6A is a diagram illustrating a process of manufacturing a semiconductor optical element;

FIG. 6B is a diagram illustrating the process of manufacturing the semiconductor optical element;

FIG. 6C is a diagram illustrating the process of manufacturing the semiconductor optical element;

FIG. 6D is a diagram illustrating the process of manufacturing the semiconductor optical element;

FIG. 6E is a diagram illustrating the process of manufacturing the semiconductor optical element;

FIG. 6F is a diagram illustrating the process of manufacturing the semiconductor optical element;

FIG. 6G is a diagram illustrating the process of manufacturing the semiconductor optical element;

FIG. 6H is a diagram illustrating the process of manufacturing the semiconductor optical element;

FIG. 6I is a diagram illustrating the process of manufacturing the semiconductor optical element;

FIG. 6J is a diagram illustrating the process of manufacturing the semiconductor optical element;

FIG. 6K is a diagram illustrating the process of manufacturing the semiconductor optical element;

FIG. 6L is a diagram illustrating the process of manufacturing the semiconductor optical element;

FIG. 7A is a diagram illustrating a modification of the process of manufacturing the semiconductor optical element;

FIG. 7B is a diagram illustrating the modification of the process of manufacturing the semiconductor optical element;

FIG. 7C is a diagram illustrating the modification of the process of manufacturing the semiconductor optical element;

FIG. 8 is a schematic diagram of a light source device using the semiconductor optical element; and

FIG. 9 is a schematic diagram of a measurement device using the semiconductor optical element.

### DETAILED DESCRIPTION

Embodiments of the present disclosure will be described below with reference to the accompanying drawings. The following description is provided for the purpose of embodying the technical ideas of the present disclosure, but the present invention is not limited to the embodiments in the following description. In the drawings, components having the same function may be denoted by the same reference numerals. Although configurations may be illustrated in separate embodiments for the sake of convenience in consideration of ease of explanation or ease of understanding of key points, such configurations illustrated in different embodiments or examples can be partially substituted or combined with one another. A description of an embodiment given after a description of another embodiment will be focused mainly on matters different from those of the already described embodiment, and a duplicate description of matters common to the already described embodiment may be omitted. The sizes, positional relationships, and the like of components illustrated in the drawings may be exaggerated for clearer illustration.

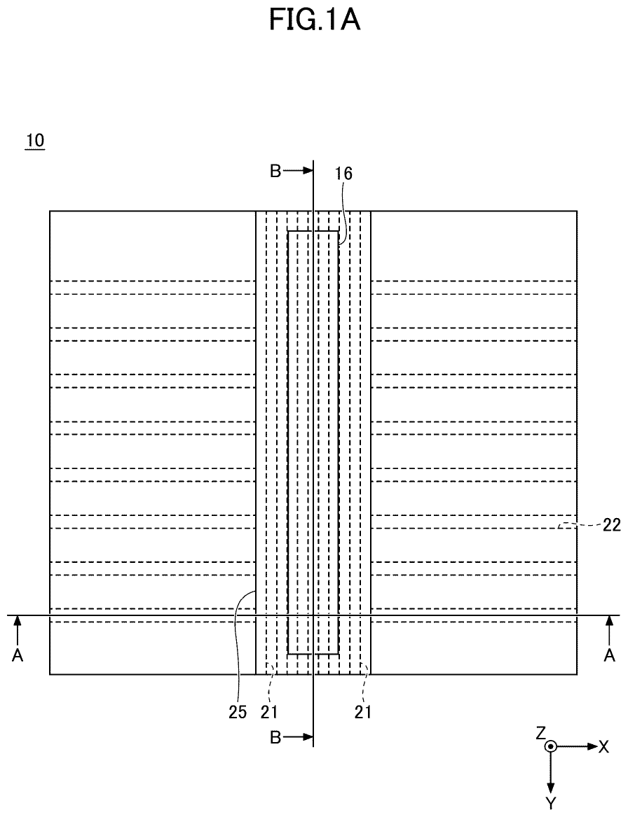

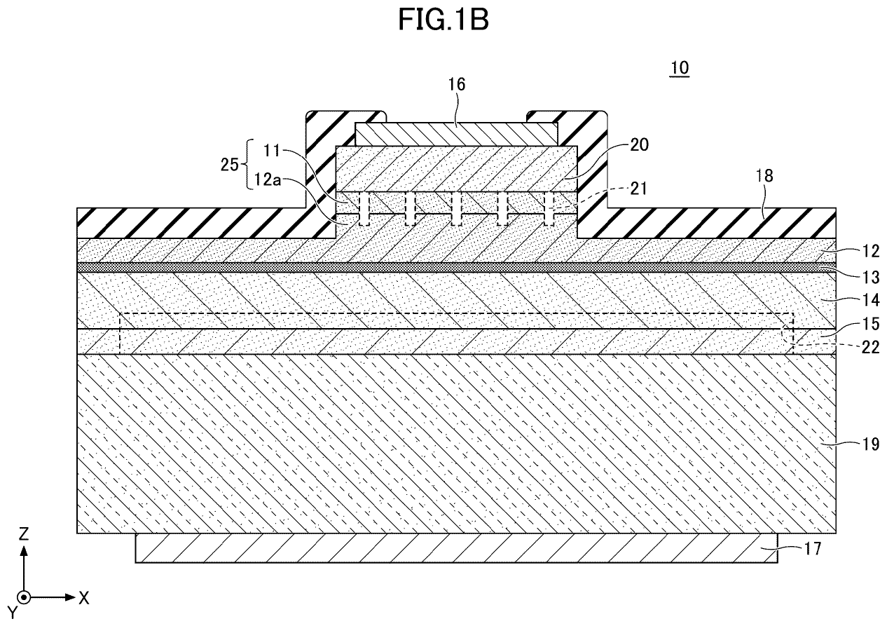

FIG. 1A is top view of a semiconductor optical element 10 according to an embodiment. FIG. 1B is a cross-sectional view of the semiconductor optical element 10 taken along line A-A of FIG. 1A. In a coordinate system used in FIG. 1A and FIG. 1B, the resonance direction of the semiconductor optical element 10 is defined as a Y direction, the layered direction of the semiconductor optical element 10 is defined as a Z direction, and the direction perpendicular to the Y direction and the Z direction is defined as an X direction. The X direction corresponds to the width direction of the semiconductor optical element 10.

The semiconductor optical element 10 includes a first indirect bandgap semiconductor part 11 that includes a first-conductivity-type impurity, a second indirect bandgap semiconductor part 12 that includes a first-conductivity-type impurity, a third indirect bandgap semiconductor part 13 that includes a second-conductivity-type impurity, a fourth indirect bandgap semiconductor part 14 that includes a second-conductivity-type impurity, and a fifth indirect bandgap semiconductor part 15 that includes a second-conductivity-type impurity at a fifth concentration. The first indirect bandgap semiconductor part, the second indirect bandgap semiconductor part 12, the third indirect bandgap semiconductor part 13, the fourth indirect bandgap semiconductor part 14, and the fifth indirect bandgap semiconductor part 15 are layered in this order. The first indirect bandgap semiconductor part 11 has one or more first recesses. The one or more first recesses contain a medium having a refractive index lower than that of the second indirect bandgap semiconductor part 12. The fifth indirect bandgap semiconductor part 15 has one or more second recesses. The one or more second recesses contain a medium having a refractive index lower than that of the fourth indirect bandgap semiconductor part 14. With this configuration, the refractive index of the first indirect bandgap semiconductor part 11 and the refractive index of the fifth indirect bandgap semiconductor part 15 can be made lower than the refractive index of the second indirect bandgap semiconductor part 12, the refractive index of the third indirect bandgap semiconductor part 13, and the refractive index of the fourth indirect bandgap semiconductor part 14. Thus, light can be efficiently confined.

The term “indirect bandgap semiconductor part” is intended to include both a case where each of the parts is a layer and a case where each of the parts is a substrate. As the material of each of the indirect bandgap semiconductor parts, silicon (Si), germanium (Ge), silicon germanium (SiGe), diamond (C), or the like may be used. One of the first conductivity type and the second conductivity type is an n-type, and the other is a p-type. In the example of FIG. 1A and FIG. 1B, the first conductivity type is the n-type, and the second conductivity type is the p-type.

The refractive index of each of the semiconductor parts can be controlled by the content of an impurity. In the semiconductor optical element 10 according to the embodiment, the impurity concentration of each of the semiconductor parts may be in a range described below. The base material of each of the indirect bandgap semiconductor parts is preferably Si. By using Si as the base material, the semiconductor optical element can be manufactured at reduced cost. Further, by using Si as the base material, an clement integrated with a light receiving element and the like can also be manufactured.

The first indirect bandgap semiconductor part 11 includes the first-conductivity-type impurity at a concentration of, for example, 1.0×10¹⁹ cm⁻³ or more and 5.0×10¹⁹ cm⁻³ or less. The concentration of the first-conductivity-type impurity included in the second indirect bandgap semiconductor part 12 is lower than the concentration of the first-conductivity-type impurity included in the first indirect bandgap semiconductor part 11. Accordingly, the refractive index of the second indirect bandgap semiconductor part 12 can be made higher than the refractive index of the first indirect bandgap semiconductor part 11. The second indirect bandgap semiconductor part 12 includes the first-conductivity-type impurity at a concentration of, for example, 1.0×10¹⁶ cm⁻³ or more and less than 1.0×10¹⁹ cm⁻³, preferably 1.0×10¹⁶ cm⁻³ or more and 5.0×10¹⁷ cm⁻³ or less, and more preferably 1.0×10¹⁶ cm⁻³ or more and 5.0−10¹⁶ cm⁻³ or less. Accordingly, the refractive index of the second indirect bandgap semiconductor part 12 can be made higher than the refractive index of the first indirect bandgap semiconductor part 11. The first-conductivity-type impurity may be, for example, phosphorus (P), arsenic (As), antimony (Sb), or the like.

The concentration of the second-conductivity-type impurity included in the third indirect bandgap semiconductor part 13 is higher than the concentration of the second-conductivity-type impurity included in the fourth indirect bandgap semiconductor part 14 described later. Accordingly, second-conductivity-type impurities that contribute to light emission can be increased. The third indirect bandgap semiconductor part 13 includes the second-conductivity-type impurity at a concentration of, for example, 1.0×10¹⁷ cm⁻³ or more and 5.0×10¹⁹ cm⁻³ or less. The concentration of the second-conductivity-type impurity included in the fourth indirect bandgap semiconductor part 14 is lower than the concentration of the second-conductivity-type impurity included in the third indirect bandgap semiconductor part 13 and the concentration of the second-conductivity-type impurity included in the fifth indirect bandgap semiconductor part 15 described later. Accordingly, the refractive index of the fourth indirect bandgap semiconductor part 14 can be made higher than the refractive index of the third indirect bandgap semiconductor part 13 and the refractive index of the fifth indirect bandgap semiconductor part 15. The fourth indirect bandgap semiconductor part 14 includes the second-conductivity-type impurity at a concentration of, for example, 1.0×10¹⁶ cm⁻³ or more and 5.0×10¹⁸ cm⁻³ or less, and more preferably 1.0×10¹⁶ cm⁻³ or more and 1.0×10¹⁷ cm⁻³ or less. The fifth indirect bandgap semiconductor part 15 includes the second-conductivity-type impurity at a concentration of, for example, 1.0×10¹⁸ cm⁻³ or more and 5.0×10¹⁹ cm⁻³ or less. Accordingly, the refractive index of the fourth indirect bandgap semiconductor part 14 can be made higher than the fifth indirect bandgap semiconductor part 15. The second-conductivity-type impurity may be boron (B), aluminum (Al), gallium (Ga), or the like.

The first indirect bandgap semiconductor part 11 and the fifth indirect bandgap semiconductor part 15 function as cladding regions for second indirect bandgap semiconductor part 12, the third indirect bandgap semiconductor part 13, and the fourth indirect bandgap semiconductor part 14. The second indirect bandgap semiconductor part 12, the third indirect bandgap semiconductor part 13, and the fourth indirect bandgap semiconductor part 14 have, as a whole, a refractive index higher than the refractive indices of the first indirect bandgap semiconductor part 11 and the fifth indirect bandgap semiconductor part 15, and function as a core region.

When light is generated by carrier recombination at the interface between the n-type second indirect bandgap semiconductor part 12 and the p-type third indirect bandgap semiconductor part 13, the light propagates through the core region, sandwiched between the first indirect bandgap semiconductor part 11 and the fifth indirect bandgap semiconductor part 15, in the resonance direction (Y direction). The carrier recombination at the interface between the second indirect bandgap semiconductor part 12 and the third indirect bandgap semiconductor part 13 may be carrier recombination according to an energy band structure generally observed at the interface of a p-n junction, or may be carrier recombination via dressed photon phonons (DPPs) as will be described later.

A plurality of first recesses 21 are formed in the first indirect bandgap semiconductor part 11. The plurality of first recesses 21 may be a plurality of grooves, holes, gaps, or the like. A plurality of second recesses 22 are formed in the fifth indirect bandgap semiconductor part 15. The plurality of second recesses may be a plurality of grooves, holes, gaps, or the like. In FIG. 1A, each of the first recesses 21 and the second recesses 22 is illustrated as a groove extending in a specific direction; however, the first recesses 21 and the second recesses 22 may be holes or gaps having any shape. In the present specification, the direction in which the first recesses 21 are arranged is also referred to as a first direction, and the direction in which the second recesses 22 are arranged is also referred to as a second direction.

At least one of the first recesses 21 or the second recesses 22 is used to enhance light confinement by reducing the effective refractive index of the corresponding cladding region. The other of the first recesses 21 and the second recesses 22 may be used for wavelength selectivity. For example, the first recesses 21 may be used to reduce the effective refractive index of the first indirect bandgap semiconductor part 11, and may be grooves, holes, gaps, or the like that contribute to reducing the effective refractive index. Hereinafter, the refractive index sensed by light propagating through a medium is referred to as an “effective refractive index,” and the relative refractive index corresponding to the type of a medium is simply referred to as a “refractive index.” The first recesses 21 may be arranged at random or may be arranged in any direction that intersects the resonance direction (Y direction) in the XY plane. In any of these cases, light can be efficiently confined by reducing the effective refractive index of the first indirect bandgap semiconductor part 11. The first direction in which the first recesses 21 are arranged is preferably a direction orthogonal to the resonance direction (Y direction) in the XY plane. Accordingly, in a case where the second recesses 22 described later are recesses for wavelength selection, the possibility that the first recesses 21 may cause unnecessary wavelength selection can be reduced.

The interval between adjacent ones of the first recesses 21 is shorter than the wavelength of laser light selected by the second recesses 22. Thus, the laser light is less likely to sense the presence of the first recesses 21. Accordingly, while the effective refractive index is reduced by the plurality of first recesses 21, unintended light confinement by the plurality of first recesses 21 can be reduced. For the same reason, the interval between adjacent ones of the first recesses 21 is preferably shorter than the pitch between adjacent ones of the second recesses 22. The interval between adjacent ones of the first recesses 21 may be, for example, 50 nm or more and 200 nm or less, and preferably 50 nm or more and 100 nm or less.

The first recesses 21 are filled with a medium having a refractive index lower than that of the second indirect bandgap semiconductor part 12. The medium having a refractive index lower than that of the second indirect bandgap semiconductor part 12 may be air or an inorganic dielectric material having a low refractive index. The refractive index of the medium with which the first recesses 21 are filled may be lower than the refractive index of the first indirect bandgap semiconductor part 11. By filling the first recesses 21 with the medium having a refractive index lower than the refractive index of the second indirect bandgap semiconductor part 12 or the refractive index of the material of the first indirect bandgap semiconductor part 11, the difference in refractive index between the first recesses 21 and the second indirect bandgap semiconductor part 12 can be increased, and thus the light confinement performance can be improved.

Each of the first recesses 21 may be provided continuously from the first indirect bandgap semiconductor part 11 to the second indirect bandgap semiconductor part 12. By forming each of the first recesses 21 so as to extend into the second indirect bandgap semiconductor part 12, a region having a refractive index between the refractive index of the first indirect bandgap semiconductor part 11 and the refractive index of the second indirect bandgap semiconductor part 12 is formed in the vicinity of the interface between the first indirect bandgap semiconductor part 11 and the second indirect bandgap semiconductor part 12. Thus, penetration of light into the first indirect bandgap semiconductor part 11 can be reduced.

The second recesses 22 may be used as recesses for wavelength selection or may be used as recesses for reducing the effective refractive index. If the second recesses 22 are used as recesses for wavelength selection, the second direction in which the second recesses 22 are arranged is along the resonance direction (Y direction). With the second recesses 22, reducing the effective refractive index and selecting a wavelength can be performed at the same time. As used herein, the expression “the second direction is along the resonance direction” includes not only a case where the second direction and the resonance direction are parallel to each other, but also a case where the second direction and the resonance direction are shifted from each other within a range of ±5 degrees or less. The second recesses 22 are filled with a medium having a refractive index lower than that of the fourth indirect bandgap semiconductor part 14. The medium having a refractive index lower than that of the fourth indirect bandgap semiconductor part 14 may be air or an inorganic dielectric material having a refractive index lower than that of the fourth indirect bandgap semiconductor part 14. Of the light propagating through the core region sandwiched between the first indirect bandgap semiconductor part 11 and the fifth indirect bandgap semiconductor part 15, light having a wavelength corresponding to a resonance wavelength determined by a periodic refractive index change of the second recesses 22 is reflected toward the fourth indirect bandgap semiconductor part 14.

A period a of the second recesses 22 may be (i) a=λ/(2×n_{eff}) or (ii) a=λ/n_{eff}, where λ is the wavelength in vacuum of light emitted from the semiconductor optical clement, and n_{eff} is the effective refractive index. In the case of (i), the semiconductor optical element 10 is an edge-emitting semiconductor laser element, In the case of (ii), the semiconductor optical element 10 is a surface-emitting semiconductor laser element. The period a may be, for example, 100 nm or more and 1,500 nm or less, and preferably 200 nm or more and 1,000 nm or less. If the wavelength is 1,300 nm, the period a may be 150 nm or more 500 nm or less, and preferably 200 nm or more and 400 nm or less. Further, if the wavelength is 1,600 nm, the period a may be 200 nm or more and 550 nm or less, and preferably 200 nm or more and 450 nm or less. Further, if the wavelength is 2,000 nm, the period a may be 300 nm or more and 700 nm or less, and preferably 400 nm or more and 600 nm or less. Further, if the wavelength is 3000 nm, the period a may be 400 nm or more and 900 nm or less, and preferably 600 nm or more and 900 nm or less. Further, if the wavelength is 4,000 nm, the period a may be 800 nm or more and 1,300 nm or less, and more preferably 800 nm or more and 1,200 nm or less. In the case of (i), the second recesses 22 may further have a λ/4 phase shift grating structure. Accordingly, wavelength selectivity can be further enhanced.

The second recesses 22 may be provided continuously from the fifth indirect bandgap semiconductor part 15 to the fourth indirect bandgap semiconductor part 14. In this case as well, by filling the second recesses 22 with the medium having a refractive index lower than that of the fourth indirect bandgap semiconductor part 14, the refractive index periodically changes in the Y direction at the interface between the fifth indirect bandgap semiconductor part 15 and the fourth indirect bandgap semiconductor part 14.

In order for the semiconductor optical element 10 to achieve wavelength selectivity and light confinement performance, a wavelength may be selected by either the first recesses 21 or the second recesses 22, and thus the first recesses 21 and the second recesses 22 may be reversed. That is, the first recesses 21 may be periodically arranged along the resonance direction (Y direction) so as to have wavelength selectivity, and the second recesses 22 may be arranged at random so as to reduce the effective refractive index of the fifth indirect bandgap semiconductor part 15. If wavelength selectivity is provided outside the semiconductor optical element 10 by adopting an external-resonator-type device configuration, both the first recesses 21 and the second recesses 22 may be used as grooves for reducing the effective refractive indices.

Referring to FIG. 1B, the semiconductor optical element 10 includes a ridge 25. The ridge 25 confines light in the horizontal direction (X direction). The ridge 25 includes the first indirect bandgap semiconductor part 11 and at least a portion 12a of the second indirect bandgap semiconductor part 12. Accordingly, the difference in refractive index can be controlled in the horizontal direction, and thus a transverse mode can be controlled. The width of the ridge 25 in the X direction may be gradually increased from the surface of the first indirect bandgap semiconductor part 11 toward the portion 12a of the second indirect bandgap semiconductor part 12. The interface between the n-type second indirect bandgap semiconductor part 12 and the p-type third indirect bandgap semiconductor part 13 is located below the ridge 25. The configuration of FIG. 1B has advantages that the amount of etching for forming the ridge 25 is small and the flatness of the lateral surfaces of the ridge 25 is easily secured.

The effective refractive index sensed by light increases at a portion where the thickness of the second indirect bandgap semiconductor part 12 is increased by the ridge 25, and thus light is confined in the vicinity of an active layer located directly below the ridge 25 in the X direction. This configuration may be referred to as an “effective refractive index waveguide type.” In the vertical direction (Z direction), light is effectively confined by the first indirect bandgap semiconductor part 11 in which the first recesses 21 are formed and the fifth indirect bandgap semiconductor part 15 in which the second recesses 22 are formed.

A layered structure including the first indirect bandgap semiconductor part 11, the second indirect bandgap semiconductor part 12, the third indirect bandgap semiconductor part 13, the fourth indirect bandgap semiconductor part 14, and the fifth indirect bandgap semiconductor part 15 may be supported on a second-conductivity-type substrate 19 that includes a second-conductivity-type (for example, p-type) impurity. The substrate 19 that includes the p-type impurity may contact the fifth indirect bandgap semiconductor part 15, and may form an end portion or a bottom portion of each of the second recesses 22. A conductive path can be secured while light is confined. A first-conductivity-type (for example, n-type) contact part 20 may be provided on the first indirect bandgap semiconductor part 11. The contact part 20 may be a first-conductivity-type substrate that includes a first-conductivity-type impurity. For example, the contact part 20 may be formed of a substrate doped with an n-type impurity. The contact part 20 may contact the first indirect bandgap semiconductor part 11, and may form an end portion of each of the first recesses 21. A conductive path can be secured while light is confined.

A p-side electrode 17 is provided on the back surface of the substrate 19 that includes the p-type impurity, and an n-side electrode 16 is provided on the contact part 20 that includes the n-type impurity. A protective film 18 covers the lateral surfaces of the ridge 25 and the surface of the second indirect bandgap semiconductor part 12, while exposing the surface of the n-side electrode 16.

Upon a current being injected into the semiconductor optical element 10 from the electrodes 16 and 17, electrons are excited, and light is generated through carrier recombination at the interface between the n-type second indirect bandgap semiconductor part 12 and the p-type third indirect bandgap semiconductor part 13. For example, the principle of light emission of an indirect bandgap semiconductor is considered as follows. That is, at the interface with the p-type third indirect bandgap semiconductor part 13 having a higher impurity concentration than the fourth indirect bandgap semiconductor part 14, dressed photons are generated by the coupling between photons and electrons in the vicinity of localized p-type impurity atoms, and the dressed photons are coupled to coherent phonons, thereby generating DPPs.

By utilizing DPPs, an energy level lower than the bottom of the conduction band is formed in the vicinity of a wave vector of holes at the top of the valence band, and light emission is stimulated on the longer wavelength side than a wavelength determined by the bandgap of the material of an indirect bandgap semiconductor part. The first indirect bandgap semiconductor part 11, the second indirect bandgap semiconductor part 12, the third indirect bandgap semiconductor part 13, the fourth indirect bandgap semiconductor part 14, and the fifth indirect bandgap semiconductor part 15 may be formed of Si. In this case, the semiconductor optical element 10 emits light having a peak wavelength of 1,100 nm or more and 4,000 nm or less in the near-infrared region to the mid-infrared region. The semiconductor optical element 10 emits light having a peak wavelength of, preferably, 1,300 nm or more and 2,500 nm or less, and more preferably 1,300 nm or more and 2,000 nm or less in the near-infrared region. Accordingly, even when the semiconductor optical element is formed of Si, light emission at a wavelength longer than a wavelength corresponding to the bandgap energy of Si can be obtained. That is, the semiconductor optical element 10 has high wavelength selectivity. In the above-described wavelength ranges, light is emitted such that a wavelength selected by the period of the first recesses 21 or the period of the second recesses 22 becomes the peak wavelength.

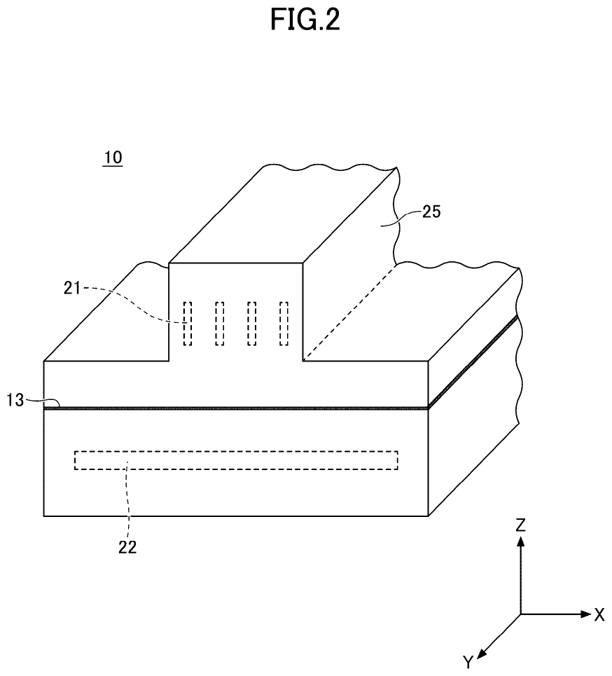

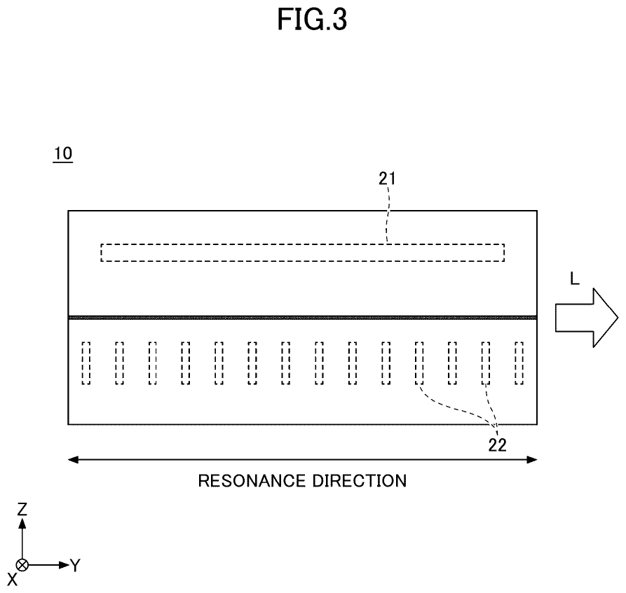

FIG. 2 is a schematic perspective view of the semiconductor optical element 10. FIG. 3 is a schematic side view of the semiconductor optical element 10 along the resonance direction (Y direction). The first recesses 21 reduce the effective refractive index of the cladding region of the semiconductor optical element 10. The first recesses 21 may be provided in the first indirect bandgap semiconductor part 11, or may be provided so as to extend from the first indirect bandgap semiconductor part 11 to the second indirect bandgap semiconductor part 12 (see FIG. 1B). In the example of FIG. 2 and FIG. 3, the first recesses 21 are illustrated as a plurality of elongated grooves extending in the Y direction. However, the first recesses 21 may have any shape as long as the effective refractive index of the cladding region can be reduced, and may be randomly-arranged holes having a cylindrical shape, a semicircular shape, or the like. The porosity of the first recesses 21 can be 0.5 times or more and 1.5 times or less the porosity of the second recesses 22. The porosity of the first recesses 21 is preferably 0.7 times or more and 1.3 times or less the porosity of the second recesses 22, and more preferably 0.9 times or more and 1.1 times or less the porosity of the second recesses 22. Accordingly, the electric field distribution of laser light can be set at a predetermined position in the layered direction of the indirect bandgap semiconductor parts. For example, a position at which a p-n junction is formed can be made to overlap the peak position of the electric field distribution. As used herein, the term “porosity” represents the area of vacancy in a region including the ridge in a cross section perpendicular to the optical axis of a waveguide.

The second recesses 22 extending in the width direction (X direction) of the semiconductor optical element 10 may be periodically provided along the resonance direction (Y direction). The second recesses 22 may be provided in the fifth indirect bandgap semiconductor part 15, or may be provided so as to extend from the fifth indirect bandgap semiconductor part 15 to the fourth indirect bandgap semiconductor part 14 (see FIG. 1B). If the second recesses 22 are used for wavelength selection, the second recesses 22 may have any shape as long as the second recesses 22 can provide a periodic refractive index change along the resonance direction (Y direction). If the second recesses 22 are used to reduce the effective refractive index of the cladding region, the second recesses 22 may be grooves, holes, gaps, or the like that are arranged at random.

A standing wave is created inside the semiconductor optical element 10 by light reciprocating in the resonance direction (Y direction) in the core region located between the first indirect bandgap semiconductor part 11 and the fifth indirect bandgap semiconductor part 15. The light is amplified such that a population inversion is maintained inside the semiconductor optical element 10, and is emitted from an end surface orthogonal to the resonance direction (Y direction) of the semiconductor optical element 10 as illustrated in FIG. 3.

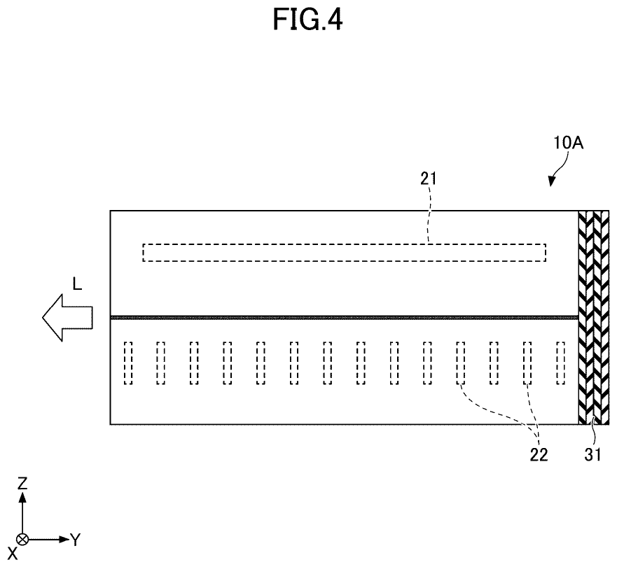

FIG. 4 is a schematic diagram illustrating a semiconductor optical element 10A that is a modification of the semiconductor optical element 10. The semiconductor optical element 10A has the same layered structure in the Z direction as in FIG. 1B, and includes a dielectric multilayer mirror 31 on one end surface orthogonal to the resonance direction (Y direction) of the semiconductor optical element 10A. For example, if the reflectance of the dielectric multilayer mirror 31 is higher than the reflectance of the end surface opposite to the end surface on which the dielectric multilayer mirror 31 is disposed, light L is emitted in a direction indicated by the arrow. The dielectric multilayer mirror 31 includes layer(s) having a high refractive index and layer(s) having a low refractive index, which are alternately arranged. The thickness of each of the layers of the dielectric multilayer mirror 31 is set such that light reflected at the interfaces of the layers is enhanced by interference.

The dielectric multilayer mirror 31 may be formed by a physical vapor deposition method such as vacuum deposition or sputtering, or may be formed by a chemical vapor deposition (CVD) method or the like. The end surface opposite to the dielectric multilayer mirror 31 may be a cleavage surface. In the case of a silicon single crystal, the (110) plane or the (111) plane is a cleavage surface. The cleavage surface may be used as a reflective surface. Alternatively, an antireflection film may be provided on the end surface opposite to the dielectric multilayer mirror 31, and a mirror constituting part of an external resonator may be provided outside the semiconductor optical element 10A. Examples of combinations of materials of the dielectric multilayer mirror include SiO₂ and TiO₂, SiO₂ and Si, SiO₂ and SiN, and the like.

FIG. 5 is a schematic diagram of a semiconductor optical element 10B that is another modification of the semiconductor optical element 10. The semiconductor optical element 10B has the same layered structure in the Z direction as in FIG. 1B. The semiconductor optical element 10B includes the dielectric multilayer mirror 31 on one end surface orthogonal to the resonance (Y) direction, and includes a high reflection film 32 on the other end surface of the semiconductor optical element 10B. The high reflection film 32 has a reflectance of 95% or more, preferably a reflectance of 98% or more, and more preferably a reflectance close to 100%. The end surface on which the high reflection film 32 is formed may be a cleavage surface or a cut surface. In the case of a cut surface, the high reflection film 32 may be formed after polishing. In the configuration of FIG. 5, either the first recesses 21 or the second recesses 22 are preferably used as grooves for wavelength selection. Light L having a predetermined wavelength is emitted from the dielectric multilayer mirror 31 while a population inversion is maintained inside the semiconductor optical element 10B.

The semiconductor optical elements 10, 10A, and 10B according to the embodiment and the modifications thereof can be used for, for example, semiconductor laser elements, semiconductor optical amplifiers, master oscillator power amplifiers (MOPAs), and the like.

### Method of Manufacturing Semiconductor Optical Element

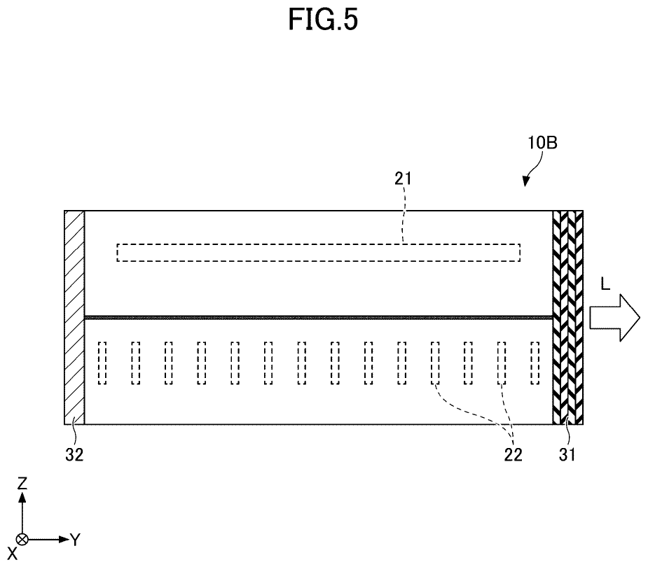

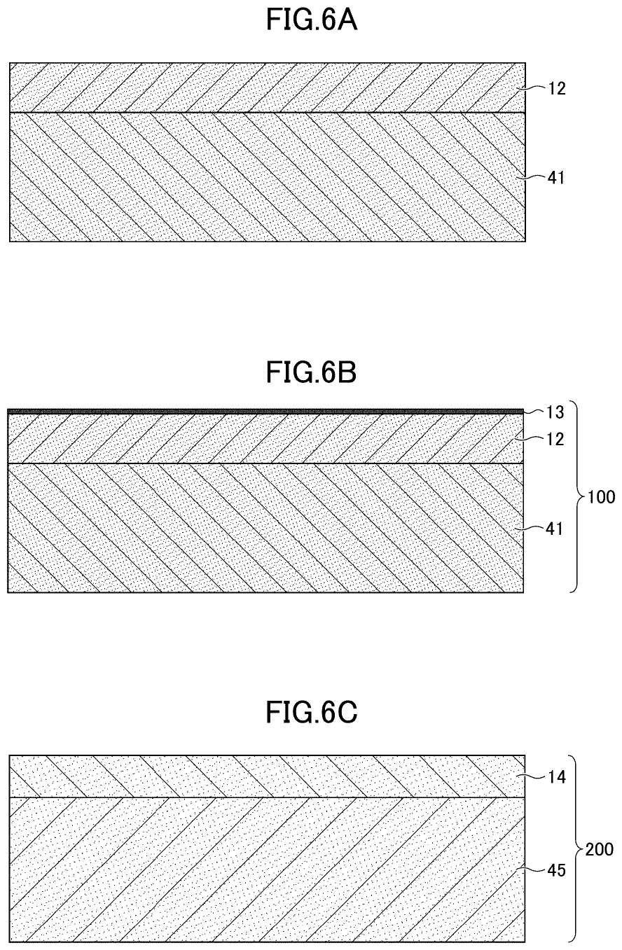

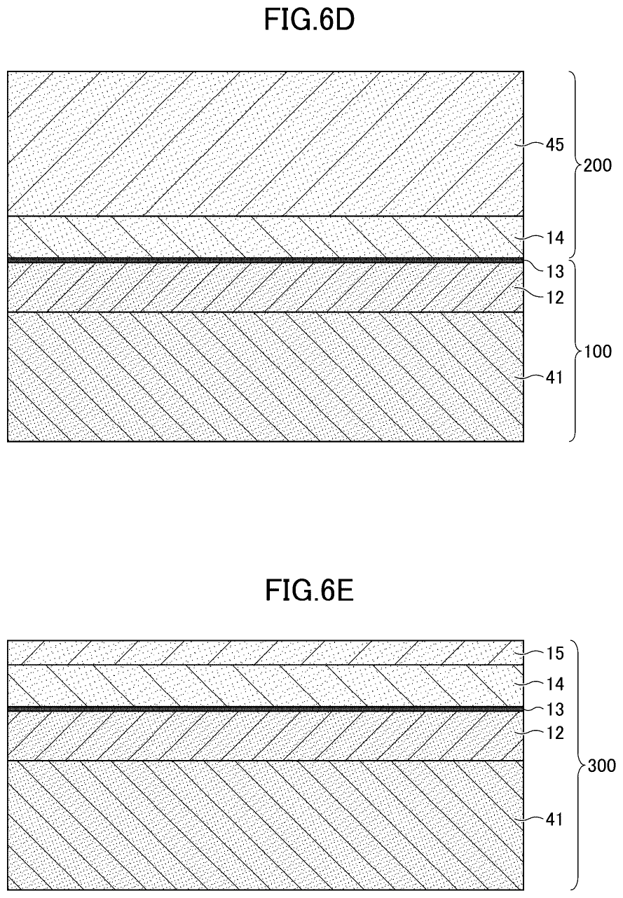

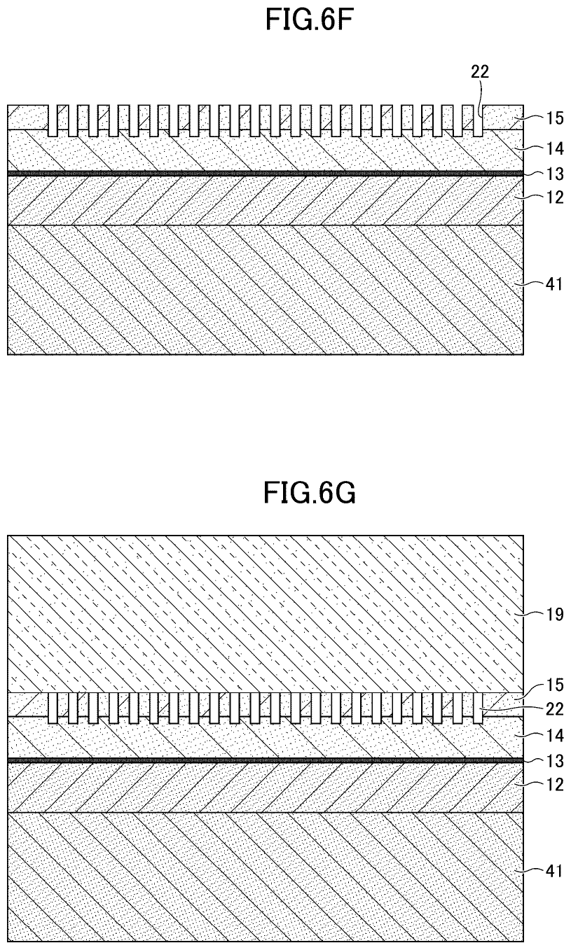

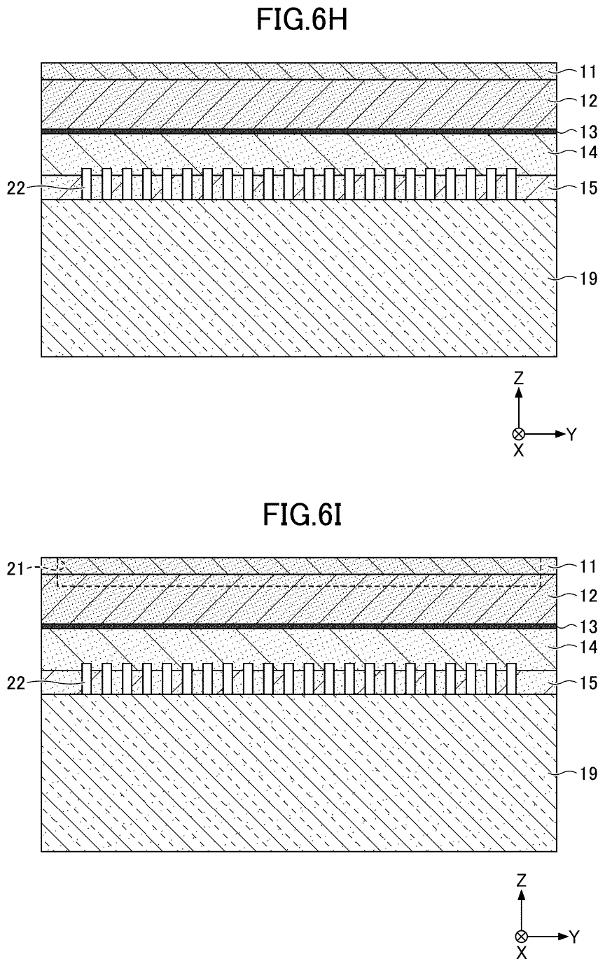

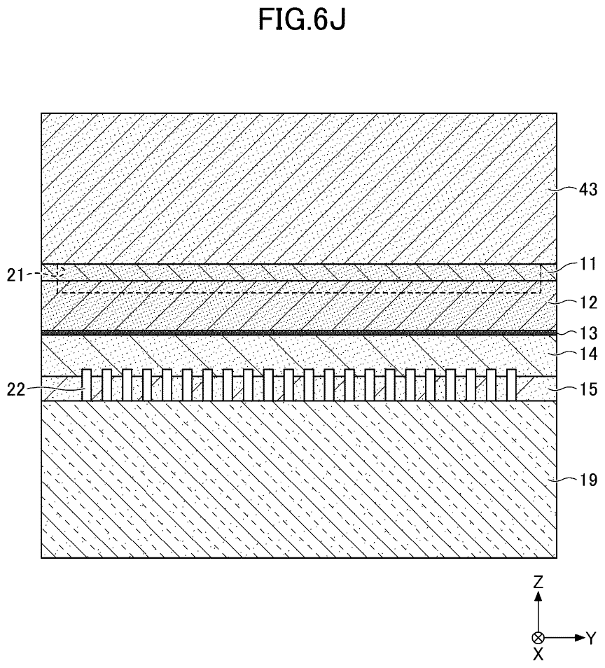

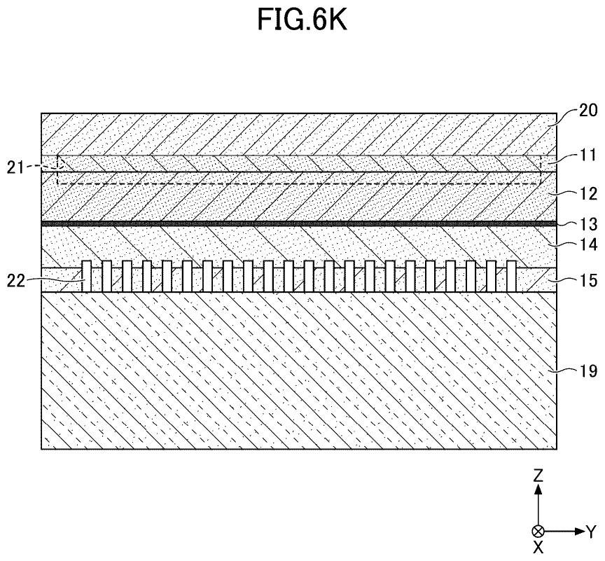

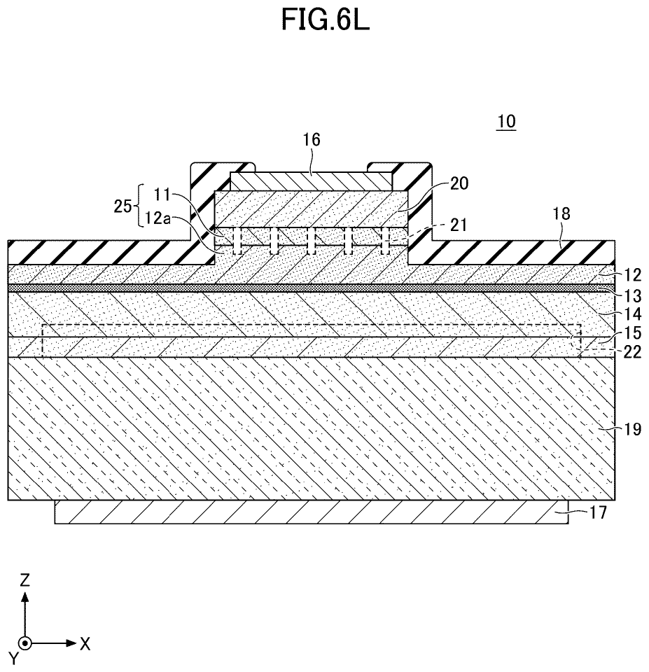

FIG. 6A through FIG. 6L are diagrams illustrating a process of manufacturing a semiconductor optical element 10. In FIG. 6A, a second indirect bandgap semiconductor part 12 is formed on a semiconductor substrate 41 that serves as a base of a first indirect bandgap semiconductor part 11. The semiconductor substrate 41 is, for example, a Si substrate that includes an n-type impurity at a predetermined concentration and has a thickness of 500 μm±50 μm. As the second indirect bandgap semiconductor part 12, a Si layer that includes an n-type impurity at a predetermined concentration is formed on the Si substrate by, for example, CVD, such that the Si layer has a thickness of approximately 2 μm. The impurity concentration of the second indirect bandgap semiconductor part 12 may be lower than the impurity concentration of the semiconductor substrate 41.

In FIG. 6B, a third indirect bandgap semiconductor part 13 is formed by implanting, at a predetermined energy, p-type impurity ions into the surface of the second indirect bandgap semiconductor part 12, that is, the surface of the second indirect bandgap semiconductor part 12 opposite to the surface that contacts the first indirect bandgap semiconductor part 11. The p-type impurity ions may be B ions, Al ions, Ga ions, or the like. By implanting the p-type impurity ions, a p-type Si layer is formed on the surface of the second indirect bandgap semiconductor part 12. For example, a p-type Si layer having a thickness of 40 nm or more and 60 nm or less is formed by implanting B ions at a dose of 1.0×10¹⁷ cm⁻³ or more and 1.0×10¹⁹ cm⁻³ or less and an acceleration energy of 10 keV or more and 1,000 keV or less. Accordingly, a first structure 100, including the n-type second indirect bandgap semiconductor part 12 and the p-type third indirect bandgap semiconductor part 13 on the semiconductor substrate 41, is obtained. The p-type impurity concentration of the third indirect bandgap semiconductor part 13 is higher than the impurity concentration of the fourth indirect bandgap semiconductor part 14 described below.

Meanwhile, in FIG. 6C, a fourth indirect bandgap semiconductor part 14 that includes a p-type impurity is formed by, for example, CVD on a semiconductor substrate 45 that includes a p-type impurity at a predetermined concentration, and as a result, a second structure 200 is obtained. The semiconductor substrate 45 may be a p-type Si substrate, and the fourth indirect bandgap semiconductor part 14 may be a p-type Si layer having a thickness of approximately 2 μm. The p-type impurity concentration of the fourth indirect bandgap semiconductor part 14 is lower than the p-type impurity concentration of the third indirect bandgap semiconductor part 13. Further, the p-type impurity concentration of the fourth indirect bandgap semiconductor part 14 may be lower than the p-type impurity concentration of the semiconductor substrate 45. The order of the steps in FIG. 6C and the steps in FIGS. 6A and 6B may be reversed, or the steps in FIG. 6C and the steps in FIGS. 6A and 6B may be performed simultaneously.

In FIG. 6D, the first structure 100 and the second structure 200 are integrated such that the p-type third indirect bandgap semiconductor part 13 of the first structure 100 and the p-type fourth indirect bandgap semiconductor part 14 of the second structure 200 face each other. Accordingly, a core region in which the third indirect bandgap semiconductor part 13 is inserted between the n-type second indirect bandgap semiconductor part 12 and the p-type fourth indirect bandgap semiconductor part 14 is obtained. Through the steps described above, a layered body is prepared in which a first indirect bandgap semiconductor part that includes a first-conductivity-type impurity, a second indirect bandgap semiconductor part that includes a first-conductivity-type impurity, a third indirect bandgap semiconductor part that includes a second-conductivity-type impurity, a fourth indirect bandgap semiconductor part that includes a second-conductivity-type impurity, and a fifth indirect bandgap semiconductor part that includes a second-conductivity-type impurity are layered in this order.

The first structure 100 and the second structure 200 may be integrated by directly bonding Si on the surface of the third indirect bandgap semiconductor part 13 and Si on the surface of the fourth indirect bandgap semiconductor part 14 without applying heat higher than a predetermined temperature. In this case, p-type impurities are unlikely to diffuse from the third indirect bandgap semiconductor part 13 to the fourth indirect bandgap semiconductor part 14. Therefore, p-type impurities do not have a stable distribution owing to heat. P-type impurities stably distributed by heat are unlikely to contribute to light emission. On the other hand, if p-type impurities have an unstable distribution, some of the p-type impurities contribute to light emission. The p-type impurities that can contribute to light emission refer to, for example, impurities at which DPPs tend to be generated. Because the impurity concentration of the third indirect bandgap semiconductor part 13 is higher than the impurity concentration of the second indirect bandgap semiconductor part 12 and the impurity concentration of the fourth indirect bandgap semiconductor part 14, the ratio of impurities contributing to light emission can be increased.

The above-described predetermined temperature may be 300° C. or less, 200° C. or less, 150° C. or less, 100° C. or less, or 50° C. or less. Alternatively, the predetermined temperature may be room temperature. The “direct bonding” refers to a bonding method without use of an intermediate member such as an adhesive. The direct bonding may be, for example, surface activated bonding. The surface activated bonding is a method of cleaning the surfaces of bonding targets in vacuum to obtain bonding surfaces, and then bonding the bonding surfaces by making the bonding surfaces contact with each other in vacuum. In the surface activated bonding, strong bonding can be obtained by atomic bonding of the bonding surfaces. In this example, the bonding targets are the third indirect bandgap semiconductor part 13 and the fourth indirect bandgap semiconductor part 14. For example, the bonding surfaces are planarized to have a surface roughness (Ra) of 1 nm or less, and irradiated with a high-speed ion beam. In this manner, the bonding surfaces are obtained. Alternatively, instead of the surface activated bonding, the third indirect bandgap semiconductor part 13 and the fourth indirect bandgap semiconductor part 14 may be bonded by atomic diffusion bonding using several atomic layers of thin metal films. The first structure 100 and the second structure 200 can be integrated at room temperature in this case as well. Regardless of the method used, it is desirable not to intentionally perform heat treatment at a temperature higher than the predetermined temperature after the bonding step. Examples of the intentional heat treatment include thermal annealing and DPP annealing. The thermal annealing typically refers to heat treatment at 800° C. or higher. The DPP annealing is a method of applying a forward current to the element while irradiating the first structure 100 with light having a predetermined wavelength. This method is sometimes performed when dressed-photon-phonons are utilized.

From the viewpoint of directly bonding the first structure 100 and the second structure 200, the surface region of the third indirect bandgap semiconductor part 13 of the first structure before integration may have an irregular atomic arrangement such as an amorphous arrangement. A region other than the surface region of the third indirect bandgap semiconductor part 13 may be amorphous or crystalline; however, it is desirable that the surface region of the third indirect bandgap semiconductor part 13 has an irregular atomic arrangement as compared to the other region.

Similarly, the surface region of the fourth indirect bandgap semiconductor part 14 of the second structure 200 before integration may have an irregular atomic arrangement such as an amorphous. A region other than the surface region of the fourth indirect bandgap semiconductor part 14 may be amorphous or crystalline; however, it is desirable that the surface region of the fourth indirect bandgap semiconductor part 14 has an irregular atomic arrangement as compared to the other region.

In FIG. 6E, a fifth indirect bandgap semiconductor part 15 is formed by polishing the substrate 45, including the p-type impurity, to a predetermined thickness (for example, 0.5 μm). Accordingly, a layered body 300 is obtained in which the semiconductor substrate 41 that includes the n-type impurity and serves as a base of the first indirect bandgap semiconductor part 11, the second indirect bandgap semiconductor part 12 that includes the n-type impurity, the third indirect bandgap semiconductor part 13 that includes the p-type impurity, the fourth indirect bandgap semiconductor part 14 that includes the p-type impurity, and the fifth indirect bandgap semiconductor part 15 that includes the p-type impurity are layered in this order.

FIG. 6F through FIG. 6K illustrate cross sections of the semiconductor optical element taken along B-B of FIG. 1A, that is, configurations of cross sections along the resonance (Y) direction. In FIG. 6F, a plurality of second recesses 22 are formed in the fifth indirect bandgap semiconductor part 15 of the layered body 300. The second recesses 22 may penetrate the fifth indirect bandgap semiconductor part 15, and reach the inside of the fourth indirect bandgap semiconductor part 14. The second recesses 22 are filled with a medium having a refractive index lower than that of the fourth indirect bandgap semiconductor part 14. For example, the second recesses 22 are filled with air. The second recesses 22 can be formed by subjecting an object to be processed to patterning using a mask formed by electron beam lithography, and then dry-etching the fifth indirect bandgap semiconductor part 15 and the fourth indirect bandgap semiconductor part 14. The dry etching may be stopped such that the bottom surfaces of the second recesses 22 are located in the fifth indirect bandgap semiconductor part 15. The mask may be patterned by using nanoimprint or photolithography with a short lead time.

In FIG. 6G, a substrate 19 including a p-type impurity is bonded to the fifth indirect bandgap semiconductor part 15 in which the second recesses 22 are formed. This bonding may be surface activated bonding between Si.

In FIG. 6H, the first indirect bandgap semiconductor part 11 is formed by polishing the substrate 41, including the n-type impurity, to a predetermined thickness (for example, 0.5 μm).

In FIG. 6I, a plurality of first recesses 21 are formed in the first indirect bandgap semiconductor part 11. The first recesses 21 may be formed only in a region where a ridge 25 is formed in a subsequent step. The first recesses 21 may penetrate the first indirect bandgap semiconductor part 11 in the depth direction, and reach the inside of the second indirect bandgap semiconductor part 12. The first recesses 21 are filled with a medium having a lower refractive index than that of the second indirect bandgap semiconductor part 12. For example, the first recesses 21 are filled with air. Similar to the second recesses 22, the first recesses 21 can be formed by subjecting an object to be processed to patterning using a mask formed by nanoimprint, electron beam lithography, or photolithography, and then dry-etching the first indirect bandgap semiconductor part 11 and the second indirect bandgap semiconductor part 12. The dry etching may be stopped such that the bottom surfaces of the first recesses 21 are located in the first indirect bandgap semiconductor part 11.

In FIG. 6J, a substrate 43 including a n-type impurity is bonded to the first indirect bandgap semiconductor part 11 in which the first recesses 21 are formed. This bonding may be surface activated bonding between Si. The order of forming the first recesses 21 and forming the second recesses 22 may be reversed. That is, after the first structure 100 and the second structure 200 are bonded in FIG. 6D, first, the n-type semiconductor substrate 41 may be polished, the first recesses 21 may be formed in the first indirect bandgap semiconductor part 11, and then the n-type substrate 43 may be bonded to close the first recesses 21 (FIG. 6H through FIG. 6J). Subsequently, the p-type semiconductor substrate 45 may be polished, the second recesses 22 may be formed in the fifth indirect bandgap semiconductor part 15, and then the p-type substrate 19 may be bonded (FIG. 6E through FIG. 6G). A conductive path can be secured while light is confined.

In FIG. 6K, the substrate 43 is polished to a predetermined thickness (for example, 2 μm). The polished substrate may be used as a contact part 20 with an n-side electrode.

FIG. 6L illustrates a configuration of cross section of the semiconductor optical clement taken along A-A of FIG. 1A. In FIG. 6L, a p-side electrode 17 is formed on the back surface of the substrate 19, and an n-side electrode 16 is formed on the surface of the contact part 20 by a lift-off method or the like. Subsequently, the ridge 25 is formed by etching a portion of the contact part 20, a portion of the first indirect bandgap semiconductor part 11, and a portion of the second indirect bandgap semiconductor part 12. The ridge 25 includes the first indirect bandgap semiconductor part 11 and a portion 12a of the second indirect bandgap semiconductor part 12. A protective film 18 is formed so as to cover the lateral surfaces of the ridge 25 and the surface of the second indirect bandgap semiconductor part 12, while exposing the surface of the electrode 16. In this manner, the semiconductor optical element 10 is obtained.

The n-side electrode 16 may be formed of, for example, a Ti/Pt/Au film. The p-side electrode 17 may be formed of a Cr/Pt/Au film. If the semiconductor optical clement 10 is driven by utilizing DPPs at the interface between the second indirect bandgap semiconductor part 12 and the third indirect bandgap semiconductor part 13, at least one of the electrode 16 or the electrode 17 may be a transparent electrode.

### Modification of Manufacturing Process

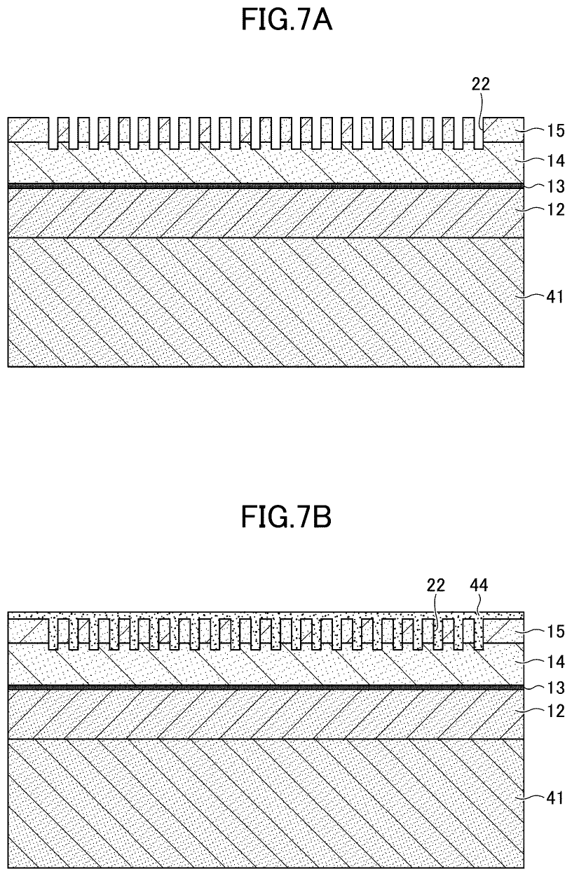

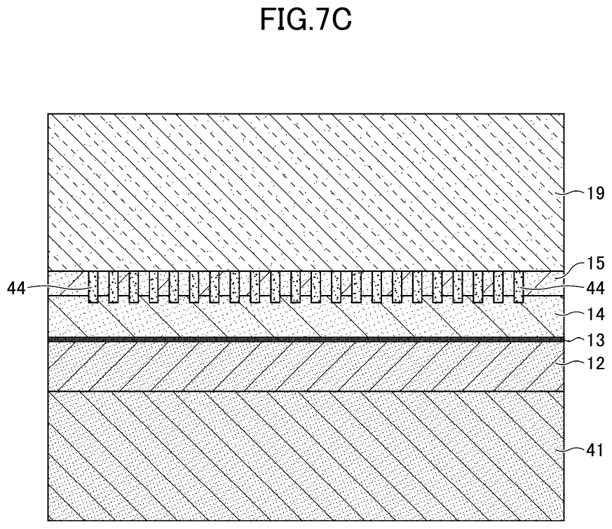

FIG. 7A through FIG. 7C illustrate a modification of the manufacturing process of the semiconductor optical clement 10. In FIG. 6F and FIG. 6G, after the second recesses 22 are formed in the fifth indirect bandgap semiconductor part 15, the p-type substrate 19 is bonded to close the second recesses 22 such that the second recesses 22 are hollow. In the modification, after the second recesses 22 are formed in FIG. 7A, the second recesses 22 may be filled with a low-refractive-index material 44 having a refractive index lower than that of the fourth indirect bandgap semiconductor part 14 in FIG. 7B, and the substrate 19 may be bonded to the fifth indirect bandgap semiconductor part 15 via the low-refractive index material 44. Similarly, after the first recesses 21 are formed in the first indirect bandgap semiconductor part 11 in FIG. 61, the first recesses 21 may be filled with a low-refractive-index material having a refractive index lower than that of the second indirect bandgap semiconductor part 12, and the substrate 43 may be bonded to the first indirect bandgap semiconductor part 11 via the low-refractive-index material.

### Practical Application

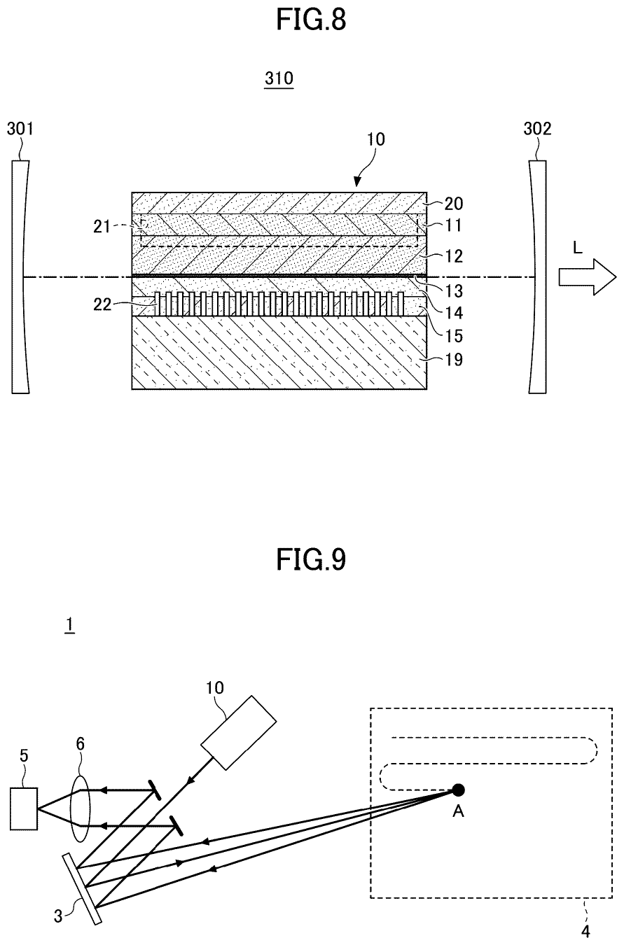

FIG. 8 is a schematic diagram of a light source device 310 using the semiconductor optical element 10. The light source device 310 includes a first mirror 301, a second mirror 302, and the semiconductor optical element 10 disposed between the first mirror 301 and the second mirror 302. The first mirror 301 and the second mirror 302 constitute an external resonator. In this example, the semiconductor optical element is used as a gain medium. Light generated in the semiconductor optical element 10 passes through the second indirect bandgap semiconductor part 12, the third indirect bandgap semiconductor part 13, and the fourth indirect bandgap semiconductor part 14, which serve as a core region, is amplified while reciprocating between the first mirror 301 and the second mirror 302, and is output from one of the mirrors (for example, from the second mirror 302). In FIG. 8, electrodes are not depicted for convenience of illustration. However, the semiconductor optical element 10 includes electrodes as illustrated in FIG. 1B, and is driven by current injection. Alternatively, the semiconductor optical element 10 may be driven by optical excitation without including electrodes. Antireflection films may be formed on the end surface of the semiconductor optical element 10 facing the first mirror 301 and on the end surface of the semiconductor optical element 10 facing the second mirror 302. The distance between the first mirror 301 and the second mirror 302 is set to an integral multiple of an oscillation wavelength.

Instead of using spatially separted optical elements, a diffraction grating mirror or a ring mirror, formed of an Si wire waveguide on an Si substrate, may be used as at least one of the first mirror 301 or the second mirror 302. The semiconductor optical element 10 may be formed on a Si substrate, a high reflection film may be provided on one of the end surfaces orthogonal to the resonance direction (optical axis) of the semiconductor optical element 10, and the high reflection film may be used as one of the mirrors constituting the external resonator. A current source for current application or a laser element for optical excitation may be included in the light source device 310.

FIG. 9 is a schematic diagram of a measurement device 1 using the semiconductor optical element 10. The measurement device 1 includes the semiconductor optical element 10 and a light receiving element 5 configured to detect reflected light of light emitted from the semiconductor optical element 10. The measurement device 1 further includes a scanning mirror 3 and a condenser lens 6.

Light emitted from the semiconductor optical element 10 is scanned by the scanning mirror 3 and directed to a distance measurement region 4 where an object is present. Return light reflected by scanning points A on the object is reflected by the scanning mirror 3, is guided to the condensing lens 6 using an additional optical element as necessary, and is incident on the light receiving element 5. The distance to the object is measured by a time-of-flight (TOF) method based on the time of flight from emission of the light from the semiconductor optical element 10 to detection by the light receiving element 5. By collecting data of the scanning points A, the object can be three-dimensionally captured.

Although the semiconductor optical element and the method of manufacturing the same according to the embodiment have been described based on the specific example configurations, the present invention is not limited to the above-described example configurations. Both the first recesses 21 and the second recesses 22 of the semiconductor optical element 10 may be formed as grooves, holes, gaps, or the like having any shape, so as to reduce the effective refractive index. If the semiconductor optical element 10 is driven via DPPs, light may be emitted simultaneously with current injection. In any of these cases, the semiconductor optical element having high light confinement performance and the method for manufacturing the semiconductor optical element can be achieved. The semiconductor optical element may be spontaneously subjected to DPP annealing in the course of being driven. In the embodiment, the principle of light emission of the semiconductor optical element has been described by taking DPPs as an example. However, the principle of light emission is not limited to DPPs. The principle of light emission of the semiconductor optical element may be, for example, light emission via an impurity level or light emission via a level derived from a defect or dislocation.

According to one embodiment of the present disclosure, a semiconductor optical element using an indirect bandgap semiconductor and a method of manufacturing the semiconductor optical element are achieved.

### OTHER CONFIGURATIONS

Furthermore, for example, the present disclosure can be configured as follows.

### Clause 1

A semiconductor optical element comprising:
a first indirect bandgap semiconductor part that includes a first-conductivity-type impurity;
a second indirect bandgap semiconductor part that includes a first-conductivity-type impurity;
a third indirect bandgap semiconductor part that includes a second-conductivity-type impurity;
a fourth indirect bandgap semiconductor part that includes a second-conductivity-type impurity; and
a fifth indirect bandgap semiconductor part that includes a second-conductivity-type impurity, wherein
the first indirect bandgap semiconductor part, the second indirect bandgap semiconductor part, the third indirect bandgap semiconductor part, the fourth indirect bandgap semiconductor part, and the fifth indirect bandgap semiconductor part are layered in this order,
the first indirect bandgap semiconductor part has one or more first recesses, the one or more first recesses containing a medium having a refractive index lower than a refractive index of the second indirect bandgap semiconductor part, and
the fifth indirect bandgap semiconductor part has one or more second recesses, the one or more second recesses containing a medium having a refractive index lower than a refractive index of the fourth indirect bandgap semiconductor part.

### Clause 2

The semiconductor optical element according to Clause 1, further comprising a ridge, wherein
the ridge includes the first indirect bandgap semiconductor part and at least a portion of the second indirect bandgap semiconductor part.

### Clause 3

The semiconductor optical element according to Clauses 1 or 2, wherein
the one or more first recesses of the first indirect bandgap semiconductor part include a plurality of first recesses,
the plurality of first recesses are arranged at least in a first direction, and
the first direction intersects a resonance direction of the semiconductor optical element.

### Clause 4

The semiconductor optical element according to any one of Clauses 1 to 3, wherein
the one or more second recesses of the fifth indirect bandgap semiconductor part include a plurality of second recesses,
the plurality of second recesses are periodically arranged at least in a second direction, and
the second direction is along a resonance direction of the semiconductor optical element.

### Clause 5

The semiconductor optical element according to any one of Clauses 1 to 4, wherein each of the one or more first recesses is provided continuously from the first indirect bandgap semiconductor part to the second indirect bandgap semiconductor part.

### Clause 6

The semiconductor optical element according to any one of Clauses 1 to 5, wherein each of the one or more second recesses is provided continuously from the fifth indirect bandgap semiconductor part to the fourth indirect bandgap semiconductor part.

### Clause 7

The semiconductor optical element according to any one od Clauses 1 to 6, wherein a material of the first indirect bandgap semiconductor part, the second indirect bandgap semiconductor part, the third indirect bandgap semiconductor part, the fourth indirect bandgap semiconductor part, and the fifth indirect bandgap semiconductor part is silicon.

### Clause 8

The semiconductor optical element according to any one of Clauses 1 to 7, further comprising:
a first-conductivity-type substrate that includes a first-conductivity-type impurity, contacts the first indirect bandgap semiconductor part, and forms an end portion of each of the one or more first recesses; and
a second-conductivity-type substrate that includes a second-conductivity-type impurity, contacts the fifth indirect bandgap semiconductor part, and forms an end portion of each of the one or more second recesses.

### Clause 9

The semiconductor optical element according to any one of Clauses 1 to 8, wherein the semiconductor optical element is configured to emit light having a peak wavelength of 1,100 nm or more and 4,000 nm or less.

### Clause 10

A light source device comprising:
a first mirror;
a second mirror; and
the semiconductor optical element of any one of Clauses 1 to 9 provided between the first mirror and the second mirror.

### Clause 11

A measurement device comprising:
the semiconductor optical element of any one of Clauses 1 to 9; and
a light receiving element configured to detect reflected light of light emitted from the semiconductor optical element.

### Clause 12

A method of manufacturing a semiconductor optical element, the method comprising:
preparing a layered body in which a first indirect bandgap semiconductor part that includes a first-conductivity-type impurity, a second indirect bandgap semiconductor part that includes a first-conductivity-type impurity, a third indirect bandgap semiconductor part that includes a second-conductivity-type impurity, a fourth indirect bandgap semiconductor part that includes a second-conductivity-type impurity, and a fifth indirect bandgap semiconductor part that includes a second-conductivity-type impurity are layered in this order;
forming one or more first recesses in the first indirect bandgap semiconductor part of the layered body, the one or more first recesses containing a medium having a refractive index lower than a refractive index of the second indirect bandgap semiconductor part; and
forming one or more second recesses in the fifth indirect bandgap semiconductor part of the layered body, the one or more second recesses containing a medium having a refractive index lower than a refractive index of the fourth indirect bandgap semiconductor part.

### Clause 13

The method of manufacturing the semiconductor optical element according to Clause 12, further comprising:
closing the one or more first recesses by bonding the first indirect bandgap semiconductor part and a first-conductivity-type substrate that includes a first-conductivity-type impurity; and
closing the one or more second recesses by bonding the fifth indirect bandgap semiconductor part and a second-conductivity-type substrate that includes a second-conductivity-type impurity.

What is claimed is:

1. A semiconductor optical element comprising:
a first indirect bandgap semiconductor part that includes a first-conductivity-type impurity;
a second indirect bandgap semiconductor part that includes a first-conductivity-type impurity;
a third indirect bandgap semiconductor part that includes a second-conductivity-type impurity;
a fourth indirect bandgap semiconductor part that includes a second-conductivity-type impurity; and
a fifth indirect bandgap semiconductor part that includes a second-conductivity-type impurity, wherein:
the first indirect bandgap semiconductor part, the second indirect bandgap semiconductor part, the third indirect bandgap semiconductor part, the fourth indirect bandgap semiconductor part, and the fifth indirect bandgap semiconductor part are layered in this order,
the first indirect bandgap semiconductor part has one or more first recesses, the one or more first recesses containing a medium having a refractive index lower than a refractive index of the second indirect bandgap semiconductor part, and
the fifth indirect bandgap semiconductor part has one or more second recesses, the one or more second recesses containing a medium having a refractive index lower than a refractive index of the fourth indirect bandgap semiconductor part.

2. The semiconductor optical element according to claim 1, comprising:
a ridge that comprises the first indirect bandgap semiconductor part and at least a portion of the second indirect bandgap semiconductor part.

3. The semiconductor optical element according to claim 1, wherein:
the one or more first recesses of the first indirect bandgap semiconductor part comprise a plurality of first recesses arranged at least in a first direction that intersects a resonance direction of the semiconductor optical element.

4. The semiconductor optical element according to claim 2, wherein:
the one or more first recesses of the first indirect bandgap semiconductor part comprise a plurality of first recesses arranged at least in a first direction that intersects a resonance direction of the semiconductor optical element.

5. The semiconductor optical element according to claim 1, wherein:
the one or more second recesses of the fifth indirect bandgap semiconductor part comprise a plurality of second recesses periodically arranged at least in a second direction along a resonance direction of the semiconductor optical element.

6. The semiconductor optical element according to claim 2, wherein:
the one or more second recesses of the fifth indirect bandgap semiconductor part comprise a plurality of second recesses periodically arranged at least in a second direction along a resonance direction of the semiconductor optical element.

7. The semiconductor optical element according to claim 4, wherein:
the one or more second recesses of the fifth indirect bandgap semiconductor part comprise a plurality of second recesses periodically arranged at least in a second direction along a resonance direction of the semiconductor optical element.

8. The semiconductor optical element according to claim 1, wherein each of the one or more first recesses is provided continuously from the first indirect bandgap semiconductor part to the second indirect bandgap semiconductor part.

9. The semiconductor optical element according to claim 2, wherein each of the one or more first recesses is provided continuously from the first indirect bandgap semiconductor part to the second indirect bandgap semiconductor part.

10. The semiconductor optical element according to claim 1, wherein each of the one or more second recesses is provided continuously from the fifth indirect bandgap semiconductor part to the fourth indirect bandgap semiconductor part.

11. The semiconductor optical element according to claim 5, wherein each of the one or more second recesses is provided continuously from the fifth indirect bandgap semiconductor part to the fourth indirect bandgap semiconductor part.

12. The semiconductor optical element according to claim 1, wherein a material of the first indirect bandgap semiconductor part, the second indirect bandgap semiconductor part, the third indirect bandgap semiconductor part, the fourth indirect bandgap semiconductor part, and the fifth indirect bandgap semiconductor part is silicon.

13. The semiconductor optical element according to claim 1, further comprising:
a first-conductivity-type substrate that includes a first-conductivity-type impurity, contacts the first indirect bandgap semiconductor part, and forms an end portion of each of the one or more first recesses; and
a second-conductivity-type substrate that includes a second-conductivity-type impurity, contacts the fifth indirect bandgap semiconductor part, and forms an end portion of each of the one or more second recesses.

14. The semiconductor optical element according to claim 2, further comprising:
a first-conductivity-type substrate that includes a first-conductivity-type impurity, contacts the first indirect bandgap semiconductor part, and forms an end portion of each of the one or more first recesses; and
a second-conductivity-type substrate that includes a second-conductivity-type impurity, contacts the fifth indirect bandgap semiconductor part, and forms an end portion of each of the one or more second recesses.

15. The semiconductor optical element according to claim 7, further comprising:
a first-conductivity-type substrate that includes a first-conductivity-type impurity, contacts the first indirect bandgap semiconductor part, and forms an end portion of each of the one or more first recesses; and
a second-conductivity-type substrate that includes a second-conductivity-type impurity, contacts the fifth indirect bandgap semiconductor part, and forms an end portion of each of the one or more second recesses.

16. The semiconductor optical element according to claim 1, wherein the semiconductor optical element is configured to emit light having a peak wavelength of 1,100 nm or more and 4,000 nm or less.

17. A light source device comprising:
a first mirror;
a second mirror; and
the semiconductor optical element of claim 1 located between the first mirror and the second mirror.

18. A measurement device comprising:
the semiconductor optical element of claim 1; and
a light receiving element configured to detect reflected light of light emitted from the semiconductor optical element.

19. A method of manufacturing a semiconductor optical element, the method comprising:
preparing a layered body in which a first indirect bandgap semiconductor part that includes a first-conductivity-type impurity, a second indirect bandgap semiconductor part that includes a first-conductivity-type impurity, a third indirect bandgap semiconductor part that includes a second-conductivity-type impurity, a fourth indirect bandgap semiconductor part that includes a second-conductivity-type impurity, and a fifth indirect bandgap semiconductor part that includes a second-conductivity-type impurity are layered in this order;
forming one or more first recesses in the first indirect bandgap semiconductor part of the layered body, the one or more first recesses containing a medium having a refractive index lower than a refractive index of the second indirect bandgap semiconductor part; and
forming one or more second recesses in the fifth indirect bandgap semiconductor part of the layered body, the one or more second recesses containing a medium having a refractive index lower than a refractive index of the fourth indirect bandgap semiconductor part.

20. The method of manufacturing the semiconductor optical element according to claim 12, further comprising:
closing the one or more first recesses by bonding the first indirect bandgap semiconductor part and a first-conductivity-type substrate that includes a first-conductivity-type impurity; and
closing the one or more second recesses by bonding the fifth indirect bandgap semiconductor part and a second-conductivity-type substrate that includes a second-conductivity-type impurity.
